(19) United States
(12) Patent Application Publication
(10) Pub. No.: US 2022/0319882 A1
(43) Pub. Date: Oct. 6, 2022

(54) METHOD AND DEVICE FOR PICKING UP AND DEPOSITING OPTOELECTRONIC SEMICONDUCTOR CHIPS

(71) Applicant: OSRAM Opto Semiconductors GmbH, Regensburg (DE)

(72) Inventors: Tobias MEYER, Kelheim (DE); Korbinian PERZLMAIER, Regensburg (DE)

(21) Appl. No.: 17/627,554

(22) PCT Filed: Aug. 12, 2020
(86) PCT No.: PCT/EP2020/072648

§ 371 Date: Jan. 14, 2022

(30) Foreign Application Priority Data
Aug. 12, 2019 (DE) 10 2019 121 672.9

(51) Int. Cl. H01L 21/67; B65G 47/92

(52) U.S. Cl. CPC H01L 21/67144; B65G 47/92

(57) ABSTRACT

A method of picking up and depositing optoelectronic semiconductor chips comprises generating electron-hole pairs in optoelectronic semiconductor chips, thereby generating a dipole electric field in the vicinity of the respective optoelectronic semiconductor chip, generating an electric field by a pick-up tool, and picking up the optoelectronic semiconductor chips during or after generation of the electron-hole pairs by the pick-up tool and depositing them at predetermined locations.

The present application claims priority to German Patent Application No. 10 2019 121 672.9, filed with the German Patent and Trademark Office on Aug. 12, 2019. The disclosure content of German Patent Application No. 10 2019 121 672.9 is hereby incorporated into the disclosure content of the present application.

The present invention relates to a method and apparatus for picking up and depositing optoelectronic semiconductor chips.

Optoelectronic semiconductor chips, in particular LEDs (English: light emitting diodes), are tested in some conventional assembly processes and sorted out if necessary before they are mounted on a circuit board. However, this can be very time-consuming and is often associated with high additional costs.

The present invention is based, inter alia, on the object of specifying a method with which optoelectronic semiconductor chips can be picked up and deposited and, at the same time, those optoelectronic semiconductor chips which have certain defects can be sorted out. Furthermore, a corresponding apparatus for picking up and depositing optoelectronic semiconductor chips is to be created.

One object of the invention is solved by a method for picking up and depositing optoelectronic semiconductor chips having the features of claim 1. A further problem of the invention is solved by an apparatus for picking up and depositing optoelectronic semiconductor chips having the features of independent claim 13. Preferred embodiments and further embodiments of the invention are indicated in the dependent claims.

A method of picking up and depositing optoelectronic semiconductor chips according to the invention comprises generating electron-hole pairs in the optoelectronic semiconductor chips.

The optoelectronic semiconductor chips may each comprise a semiconductor layer having a photosensitive region, which may also be referred to as an optically active region. This region may be, for example, the active region of a light emitting diode. In the photosensitive region, charge carriers or electron-hole pairs can be generated by a corresponding excitation, in particular by incident light.

An electron-hole pair consists of a defect electron and an electron that has been moved from its ground state in the crystal to an excited state by the absorption of energy.

Suitable properties of the semiconductor material, such as two regions with different concentrations of dopants, such as a p-n junction, can separate the electron-hole pairs from each other. This creates charges in the respective semiconductor chips that generate a dipole field outside the semiconductor chips. This process is also known as the photovoltaic effect.

The amount of dipole field generated by a particular semiconductor chip depends on characteristics of the semiconductor chip. Semiconductor chips may have defects, such as shorts, shunts, or lower efficiencies, which typically result in accelerated flow-off of the excitation-generated charges and thus a reduced dipole field.

Furthermore, according to the method according to the invention, a pick-up tool is provided which is used to pick up the optoelectronic semiconductor chips and place them at predetermined locations or places, for example on a circuit board on which the optoelectronic semiconductor chips are to be mounted. This process is also referred to as “pick and place” in the English-language technical literature.

According to the invention, the pick-up tool generates an electric field at least at certain locations, for example by being electrically charged at these locations. The optoelectronic semiconductor chips are picked up by the pick-up tool during or after the generation of the electron-hole pairs.

The electric field generated by the pick-up tool interacts with the dipole fields of the optoelectronic semiconductor chips, creating an attractive or even repulsive force between the pickup tool and the optoelectronic semiconductor chips. The electrostatic interaction or force may override an interaction or force that exists between the pick-up tool and the optoelectronic semiconductor chips even in the absence of the electric dipole fields caused by the electron-hole pairs. For example, a van der Waals attraction or an electrostatic attraction may exist between the pick-up tool and the respective optoelectronic semiconductor chips even without the dipole charge produced by the excitation. The additional electrostatic attraction may overcome a threshold above which the optoelectronic semiconductor chips are released from a carrier on which the optoelectronic semiconductor chips are disposed and are picked up by the pick-up tool.

The force required to remove the optoelectronic semiconductor chips from the carrier may be greater than the force required to hold the removed optoelectronic semiconductor chips by the pick-up tool. Therefore, in some circumstances, the electrostatic force may be required only for removing and not for holding the optoelectronic semiconductor chips. Consequently, the presence of the dipole electric fields is only necessary for removing the optoelectronic semiconductor chips, but not necessarily necessary for holding the optoelectronic semiconductor chips thereafter.

Optoelectronic semiconductor chips with certain defects, for example short circuits, shunts, low efficiency or other defects, have a lower dipole field when excited than optoelectronic semiconductor chips without such defects. Accordingly, the electrostatic interaction between the pick-up tool and the defective optoelectronic semiconductor chips is so low that they are not picked up by the pick-up tool and remain on the carrier. The invention therefore enables defective optoelectronic semiconductor chips not to be picked up and accordingly not to be mounted, whereby the repair effort caused by mounting defective optoelectronic semiconductor chips can be considerably reduced. Functional, i.e. “good” optoelectronic semiconductor chips can, however, be picked up by the pick-up tool and transferred to a new carrier, for example.

By means of a suitable embodiment, it can alternatively be effected that optoelectronic semiconductor chips with certain defects which reduce the dipole field are received by the receiving tool and “good” optoelectronic semiconductor chips with higher dipole fields are repelled by the receiving tool and remain on the carrier. This embodiment also has the effect of separating good and defective optoelectronic semiconductor chips.

The pick-up tool may be made of a suitable material to generate an electric field. For example, the pick-up tool may comprise polydimethylsiloxane (PDMS for short) in which metal contacts are embedded. The metal contacts may be connected to an electrical voltage source to appropriately charge the PDMS material to generate the electric field.

Further, the pick-up tool may be made of a suitable electrically charged material that inherently generates an electric field.

Another option for generating the electric field is to generate the electric field, for example, through contacts inside or on the surface of the pick-up tool and an electric voltage.

The electric field may also extend between the pick-up tool and an electrical contact, with the optoelectronic semiconductor chips being located between the pick-up tool and the electrical contact. The electrical contact may be, for example, the carrier on which the optoelectronic semiconductor chips are deposited or may be integrated therein.

The optoelectronic semiconductor chips can be produced on a semiconductor wafer and then separated, for example by sawing. After being separated, the optoelectronic semiconductor chips can be mounted on a circuit board or other carrier using the method described herein.

The electromagnetic radiation emitted by the optoelectronic semiconductor chips may be, for example, light in the visible range, ultraviolet (UV) light, and/or infrared light.

The optoelectronic semiconductor chips can be designed, for example, as light-emitting diodes (LED), as organic light-emitting diodes (OLED), as light-emitting transistors or as organic light-emitting transistors. In various embodiments, the optoelectronic semiconductor chips may be part of an integrated circuit.

Such LEDs can be used, for example, in video walls, lighting equipment in buildings and vehicles, or ambient lighting or area lighting. Such LEDs are also used for large-area matrices in which individual LEDs are placed.

The optoelectronic semiconductor chips can be solar cells, for example.

According to one embodiment, the optoelectronic semiconductor chips are implemented as LEDs that have edge lengths in the range of 100 μm or greater. For example, the LEDs have an edge length in the range of 250 μm to 600 μm. Such LEDs may, for example, be particularly suitable for the above-mentioned application examples.

The excitation of the optoelectronic semiconductor chips to generate the electron-hole pairs can be performed by irradiating the optoelectronic semiconductor chips with light, in particular UV light. The light spectrum must comprise a wavelength or wavelength range that allows excitation, in particular photoluminescence excitation. In particular, the excitation radiation must have a higher energy than the radiation emitted by the optoelectronic semiconductor chips. Consequently, the wavelength of the excitation radiation must be shorter than the wavelength of the radiation emitted by the optoelectronic semiconductor chips. For example, blue LEDs emit light at about 460 nm. In this case, the excitation radiation should have a wavelength of 440 nm or shorter, for example a wavelength of about 420 nm.

The light used to generate the electron-hole pairs may fall through the pick-up tool onto the optoelectronic semiconductor chips. To enable this, the pick-up tool may at least partially comprise a material that is at least partially transparent or transmissive to the light. Furthermore, openings or light guides may be integrated into the pick-up tool through which the light reaches the optoelectronic semiconductor chips.

The optoelectronic semiconductor chips may be disposed on a carrier or a substrate prior to being picked up by the pick-up tool. The light used to generate the electron-hole pairs may fall through the carrier or substrate onto the optoelectronic semiconductor chips. For this purpose, the carrier or substrate may be at least partially made of a material that is at least partially transparent or transmissive to the light, or openings or light guides may be integrated into the carrier or substrate.

Alternatively, the light can be shone laterally or obliquely onto the optoelectronic semiconductor chips.

It may be provided that electron-hole pairs are not generated in all of the optoelectronic semiconductor chips, but only selectively in some of the optoelectronic semiconductor chips.

For example, a plurality of optoelectronic semiconductor chips may be provided and the electron-hole pairs are generated only in selected optoelectronic semiconductor chips of the plurality of optoelectronic semiconductor chips. Then, except for the defective optoelectronic semiconductor chips, only these optoelectronic semiconductor chips are also picked up by the pickup tool. The selective excitation of the optoelectronic semiconductor chips may be performed, for example, by passing the light for generating the electron-hole pairs through a mask.

Another way to pick up only a selection of the optoelectronic semiconductor chips is for the pick-up tool to generate an electric field only in predetermined areas. This can be made possible, for example, by the metal contacts embedded in the pick-up tool being at least partially individually controllable.

According to one embodiment, the pick-up tool has a plurality of protrusions or punches on a surface facing the optoelectronic semiconductor chips. When the pick-up tool is lowered, only the protrusions come into contact with the optoelectronic semiconductor chips, so that only the protrusions pick up optoelectronic semiconductor chips. The areas between the protrusions and the areas outside the protrusions do not receive optoelectronic semiconductor chips.

Alternatively, the pick-up tool may have, at least in one region, a continuous flat surface intended for receiving the optoelectronic semiconductor chips. This allows for greater flexibility, as optoelectronic semiconductor chips arranged in different patterns and/or with different spacing can be accommodated.

For example, the pick-up tool may be approximately the size of the semiconductor wafer on which the optoelectronic semiconductor chips are fabricated and subsequently separated, for example, by sawing.

Further, the pick-up tool may be in the form of a cylinder that is rolled over the optoelectronic semiconductor chips to pick up the optoelectronic semiconductor chips. For example, the pick-up tool may be shaped like the drum of a laser printer. To pick up the optoelectronic semiconductor chips, the cylindrical pick-up tool may be moved over the optoelectronic semiconductor chips. Alternatively, the axis of rotation of the cylindrical pick-up tool may be stationary and the carrier with the optoelectronic semiconductor chips may be slid under the pick-up tool.

To deposit the optoelectronic semiconductor chips, the electrical charge of the pick-up tool can be changed via the metal contacts. For example, the polarity of the metal contacts can be reversed. This leads to a repulsive electrical interaction between the pick-up tool and the optoelectronic semiconductor chips polarized by the electron-hole pairs.

Furthermore, the charge can also be changed only at certain locations or in certain areas of the pick-up tool, so that selectively certain optoelectronic semiconductor chips are deposited.

Another way to deposit the optoelectronic semiconductor chips is that the carrier or substrate to which the optoelectronic semiconductor chips are deposited generates an adhesive force that is greater than the attractive force between the pick-up tool and the optoelectronic semiconductor chips. For example, the surface of the carrier or substrate may be coated with an adhesive, a varnish, a solder material, or other suitable materials.

Furthermore, the optoelectronic semiconductor chips can be detached from the pick-up tool by means of mechanical forces, for example by shearing or acceleration forces.

According to one embodiment, the pick-up tool directly contacts the optoelectronic semiconductor chips to pick them up. During the transfer of the optoelectronic semiconductor chips, the pick-up tool holds them by means of Van der Waals forces.

An apparatus according to the invention is intended for picking up and depositing optoelectronic semiconductor chips. The apparatus may, for example, be an automatic placement machine or may be integrated into an automatic placement machine.

The apparatus comprises an excitation element for generating electron-hole pairs in optoelectronic semiconductor chips and a pick-up tool for picking up and depositing the optoelectronic semiconductor chips. The electron-hole pairs generate electric dipole fields in the vicinity of the optoelectronic semiconductor chips. The pick-up tool is configured to generate an electric field that interacts with the electric dipole fields of the optoelectronic semiconductor chips to pick them up. The picked up optoelectronic semiconductor chips are transferred to predetermined locations and deposited there.

According to one embodiment, the excitation element is configured to generate light having a predetermined wavelength or range of wavelengths for generating the electron-hole pairs in the optoelectronic semiconductor chips. For example, the excitation element may comprise a light source and/or a light guide.

The excitation element may be arranged such that the light for generating the electron-hole pairs is incident on the optoelectronic semiconductor chips through the pick-up tool or through a substrate on which the optoelectronic semiconductor chips are arranged.

The pick-up tool may comprise a plurality of protrusions on a surface facing the optoelectronic semiconductor chips. The optoelectronic semiconductor chips may be received by the protrusions of the receiving tool.

Alternatively, at least a portion of a surface of the pick-up tool facing the optoelectronic semiconductor chips may be planar throughout and configured to receive the optoelectronic semiconductor chips.

Further, the optoelectronic semiconductor chip pick-up and deposition apparatus may include the above-described embodiments of the optoelectronic semiconductor chip pick-up and deposition method.

Furthermore, it is possible that in the manufacturing process of the semiconductor chips within individual batches there are small deviations and thus small differences between the individual semiconductor chips. The color temperature (Kelvin) or the color and the luminous flux (lumen), the necessary forward voltage, can differ within a production batch. As a result, semiconductor chips that are installed in a single luminaire, for example, may be slightly different.

The semiconductor chips, whose key figures are broader or narrower depending on the desired quality, can be sorted into different bins—i.e. areas. This process is called binning.

From these individual bins, semiconductor chips can then be selected and arranged in relation to each other, e.g. in an individual luminaire or a video wall, in such a way that a uniform and desired color temperature or color of the luminaire or video wall is achieved in the overall image.

The method or the apparatus for picking up and depositing optoelectronic semiconductor chips can therefore be suitable, for example, for picking up the semiconductor chips according to their color temperature or color and luminous flux and either depositing them in corresponding bins or picking up semiconductor chips with a different color temperature according to a desired combination and transferring them to a new carrier or a housing component.

The method or the apparatus for picking up and depositing optoelectronic semiconductor chips can furthermore be suitable for inserting a transfer of the optoelectronic semiconductor chips, or also an intermediate stage of the semiconductor chips—for example before the semiconductor chips are separated-, into an intended housing component and thus into a final product or package. At the same time, for example, the quality and/or functionality of the components can be checked. Accordingly, an additional step of individually checking the semiconductor chips at wafer level for quality and/or functionality may be omitted. As a result, it may be possible, for example, for binning of the semiconductor chips to occur only after they have already been inserted into an intended package component and thus into a final product or package. In this case, too, an additional step of individually checking the semiconductor chips at wafer level for their quality and/or functionality can be omitted.

In the following, embodiments of the invention will be explained in more detail with reference to the accompanying drawings. In these schematically show:

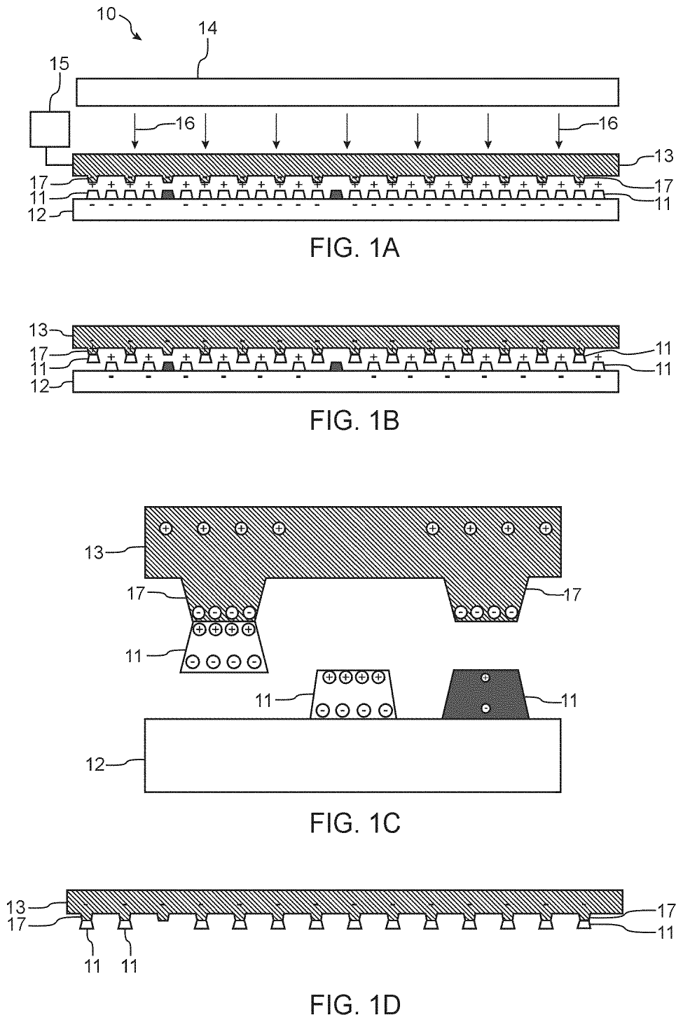

FIGS. 1A to 1D illustrations of a method and an apparatus for picking up and depositing optoelectronic semiconductor chips;

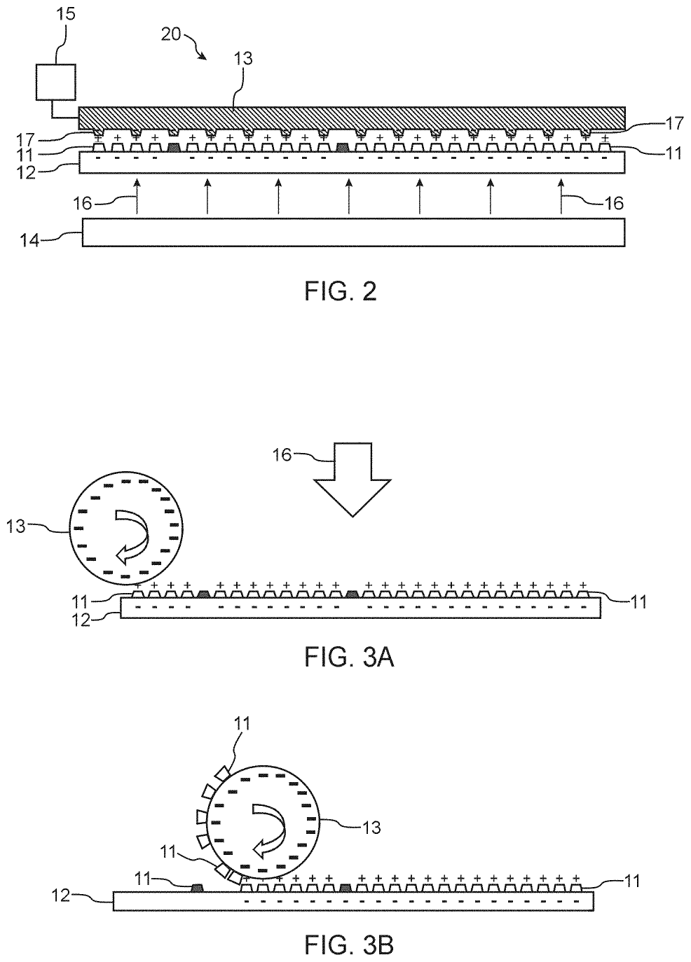

FIG. 2 an illustration of a further apparatus for picking up and depositing optoelectronic semiconductor chips;

FIGS. 3A and 3B illustrations of a method for picking up and depositing optoelectronic semiconductor chips by means of a cylindrical pick-up tool;

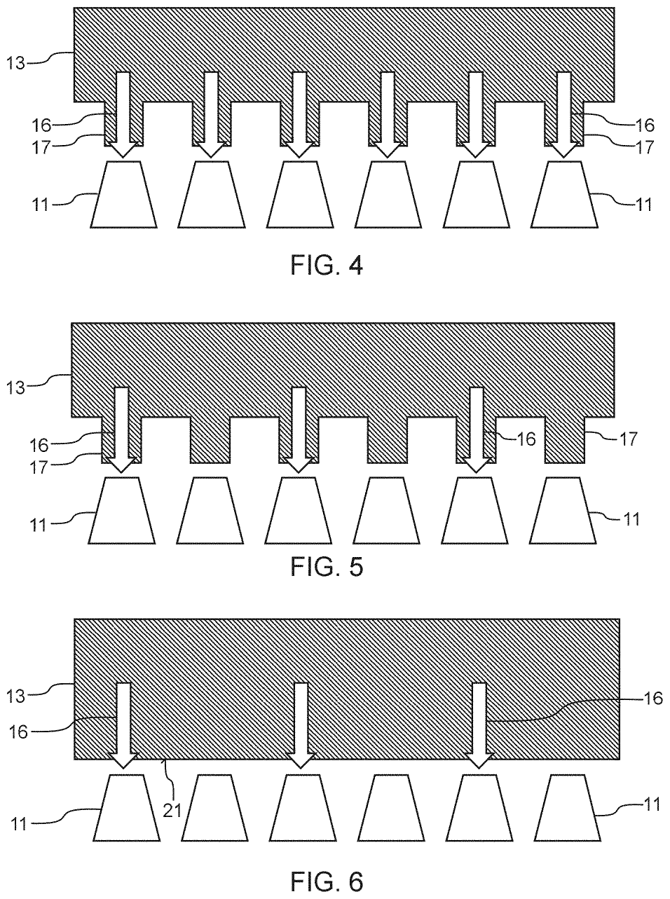

FIG. 4 an illustration of a pick-up tool with protrusions for picking up optoelectronic semiconductor chips;

FIG. 5 an illustration of a pick-up tool with selective irradiation of optoelectronic semiconductor chips;

FIG. 6 an illustration of a pick-up tool with a flat surface for picking up optoelectronic semiconductor chips;

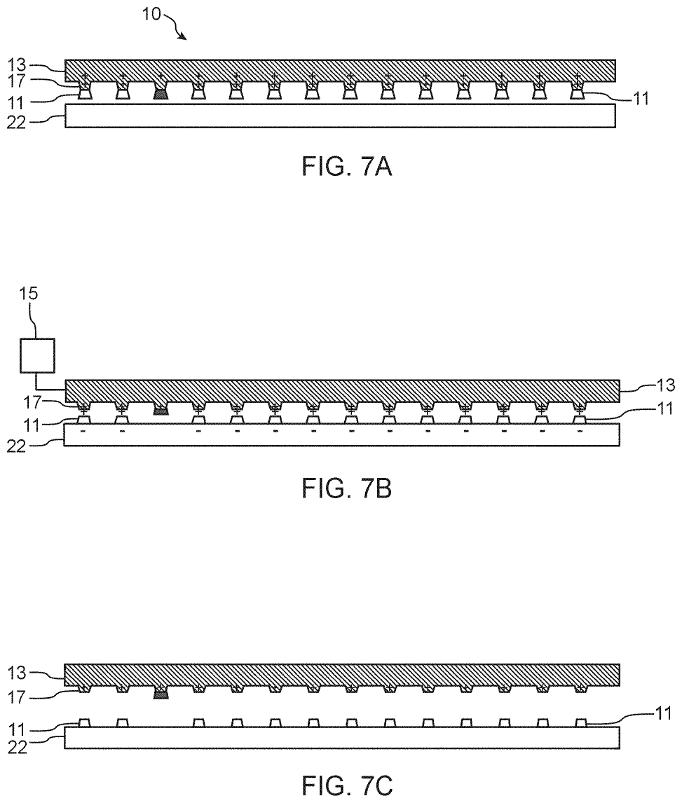

FIGS. 7A to 7C illustrations of a method of depositing optoelectronic semiconductor chips; and

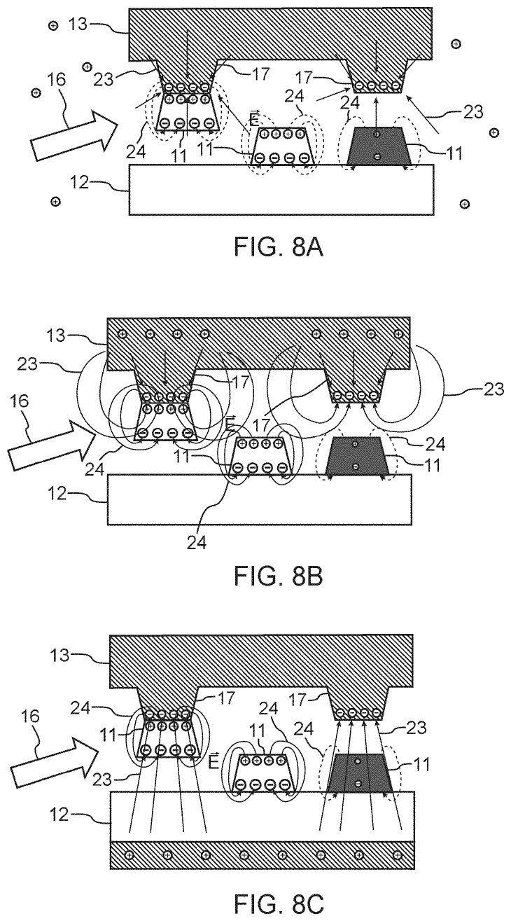

FIGS. 8A to 8C illustrations of various embodiments for generating an electric field through the pick-up tool.

In the following detailed description, reference is made to the accompanying drawings, which form a part of this description and in which are shown, for illustrative purposes, specific embodiments in which the invention may be practiced. Since components of embodiments may be positioned in a number of different orientations, the directional terminology is for illustrative purposes and is not limiting in any way. It is understood that other embodiments may be used and structural or logical changes may be made without departing from the scope of protection. It is understood that the features of the various embodiments described herein may be combined, unless specifically indicated otherwise. Therefore, the following detailed description is not to be construed in a limiting sense. In the figures, identical or similar elements are provided with identical reference signs where appropriate.

FIG. 1A schematically shows an apparatus 10 for picking up and depositing optoelectronic semiconductor chips as an example embodiment according to the invention.

In the present embodiment, the optoelectronic semiconductor chips are formed as LEDs 11 and are spaced apart from each other on a carrier 12.

The apparatus 10 comprises a pick-up tool 13, an excitation element 14, and a voltage source 15.

The excitation element 14 emits light 16 with which the LEDs 11 are irradiated. The light 16 emitted by the excitation element 14 includes wavelengths that generate electron-hole pairs in the optically active region of the LEDs 11 by excitation. The electron-hole pairs cause electrostatic polarization within the LEDs 11, thereby generating an electric dipole field in the vicinity of the respective LED 11.

In the present embodiment, the pick-up tool 13 is arranged between the excitation element 14 and the LEDs 11. The pick-up tool 13 is at least partially transparent to the light 16 emitted by the excitation element 14, so that the light 16 can reach the LEDs 11.

The pick-up tool 13 comprises metal contacts embedded, for example, in polydimethylsiloxane (PDMS for short) or other suitable material. The metal contacts are connected to the voltage source 15. An electrostatic field can be generated via a voltage across the metal contacts.

Further, the pick-up tool 13 comprises protrusions 17 extending from a surface on the underside of the pick-up tool 13 toward the LEDs 11.

With reference to FIGS. 1A to 1D, a method of picking up and depositing LEDs 11 using the apparatus 10 will be described below as an embodiment according to the invention.

The light 16 emitted from the excitation element 14 causes excitation and a resulting electrostatic polarization in the LEDs 11. At the same time, the pick-up tool 13 is charged by means of the voltage source 15 in such a way as to cause an attractive interaction between the pick-up tool 13 and the LEDs 11.

The pick-up tool 13 is moved down toward the LEDs 11 until the protrusions 17 are in contact with the LEDs 11 below. In the present embodiment, every other LED 11 is in contact with one of the protrusions 17.

As FIG. 1B shows, the pick-up tool 13 is then lifted together with the LEDs 11 adhering to the protrusions 17. FIG. 1C shows an enlarged section of FIG. 1B. FIG. 1C shows the electrostatic charge of the pick-up tool 13 and the polarization of the LEDs 11. For simplicity, FIG. 1B and all subsequent figures do not show the excitation element 14 or the voltage source 15.

LEDs 11 located between the protrusions 13 are not lifted by the pick-up tool 13. Further, LEDs 11 in which the light 16 emitted from the excitation element 14 causes little or no polarization due to defects in the LEDs 11 are not lifted. These LEDs 11 are shown with a dark background in FIGS. 1A to 1C. The lower polarization compared to intact LEDs 11 allows LEDs 11 with corresponding defects to be sorted out without having to test the LEDs 11 beforehand.

Subsequently, as shown in FIG. 1D, the LEDs 11 are transferred to a desired location by means of the pick-up tool 13 and deposited there.

FIG. 2 schematically shows an apparatus 20 for picking up and depositing optoelectronic semiconductor chips as another example of an embodiment according to the invention. The apparatus 20 shown in FIG. 2 is largely identical to the apparatus 10 of FIG. 1A. The difference is that the excitation element 14 in FIG. 2 is arranged below the carrier 12 on which the LEDs 11 are located. In this case, the support 14 must be at least partially transparent to the light 16 emitted by the excitation element 14 in order for photoluminescence excitation to occur in the LEDs 11.

FIG. 3A schematically shows a cylindrical pick-up tool 13, which may be shaped like the drum of a laser printer. The pick-up tool 13 is electrostatically charged such that an attractive interaction exists between the surface of the pick-up tool 13 and the LEDs 11 located thereunder due to the polarization caused by the photoluminescence excitation.

As shown in FIG. 3B, the cylindrical pick-up tool 13 is rolled over the support 12, picking up those LEDs 11 in which sufficient polarization has been produced by the incident light 16.

FIG. 4 schematically shows a pick-up tool 13 with protrusions 17 on its underside extending in the direction of the LEDs 11 arranged below the pick-up tool 13. The light 16 emitted by the excitation element 14, which is not shown in FIG. 4, falls through the pick-up tool 13 onto the LEDs 11.

To allow the passage of the light 16, the receiving tool 13 may be made of a material that is at least partially transparent to the light 16, or appropriate passage openings or light guides may be incorporated into the receiving tool 13.

FIG. 5 shows the pick-up tool 13 of FIG. 4, but in FIG. 5 only certain LEDs 11 are selectively irradiated with the light 16, for example every second LED 11. To make this possible, corresponding through-holes or light guides may be integrated into the pick-up tool 13, or a corresponding shading mask may be provided to allow the light 16 to fall only on the predetermined LEDs 11. As a result, only the LEDs 11 irradiated with the light 16 are excited to photoluminescence and only these LEDs 11 can be picked up by the pick-up tool 13, provided that they form a sufficient polarization due to the photoluminescence excitation.

FIG. 6 schematically shows a pick-up tool 13 having a continuous flat surface 21 on its underside. The flat surface 21 makes it possible to pick up LEDs 11 arranged in different patterns and/or at different distances.

Furthermore, shading elements, for example a mask, may be provided to selectively excite only certain LEDs 11 to photoluminescence.

FIGS. 7A to 7C show the apparatus 10 during deposition of the LEDs 11. After picking up the LEDs 11 shown in FIGS. 1A to 1D, the pick-up tool 13 is transferred to a board shown in FIG. 7A, on which some of the LEDs 11 are to be mounted.

By means of the voltage source 15 shown in FIG. 7B, the electrostatic charge of the pick-up tool 13 is changed such that the attractive interaction between the pick-up tool 13 and the LEDs 11 is reduced or converted into a repulsive interaction. By means of the individually controllable metal contacts in the pick-up tool, the electrical charge in certain areas of the pick-up tool can be changed in the desired manner so that only a predetermined number of the LEDs 11 are deposited on the circuit board 22. The pick-up tool 13 is then removed from the circuit board 22, as shown in FIG. 7C. The LEDs 11 remaining on the pick-up tool 13 may be removed or deposited elsewhere, for example on a cleaning adhesive strip.

FIGS. 8A to 8C schematically illustrate various options for how an electric field can be generated by the pick-up tool 13. The field lines 23 shown in FIGS. 8A to 8C indicate the direction and strength of the electric field at the respective location.

In the embodiment shown in FIG. 8A, charges are located in the protrusions 17 of the pick-up tool 13. The counter charges are located in the vicinity of the pick-up tool 13. This results in an electric field in the vicinity of each of the protrusions 17 that is similar to the field of a point charge.

In FIG. 8B, dipole charges are located in the pick-up tool 13 such that the electric field strength at the tips of the bumps 17 is particularly large.

In FIG. 8C, the protrusions 17 of the pick-up tool 13 are electrically charged and the counter charges are arranged below the carrier 12, so that the LEDs 11 to be picked up are located between the pick-up tool 13 and the counter charges and thus within the electric field.

The electric fields generated by means of the pick-up tool 13 should not be homogeneous in order to exert an effective force on the dipoles of the LEDs 11 so that they can be picked up by the support 12.

FIGS. 8A to 8C also show electric field lines 24 of the LEDs 11 generated by the excitation. The interaction of the field lines 24 of the LEDs 11 with the field lines 23 of the pick-up tool 13 is not shown for simplicity.

### LIST OF REFERENCE SIGNS

10 Apparatus
11 LED
12 Carrier
13 Pick-up tool
14 Excitation element
15 Voltage source
16 Light
17 Survey
20 Apparatus
21 Surface
22 Board
23 Field line of the pick-up tool
24 Field line of the semiconductor chip

1. A method for picking up and depositing optoelectronic semiconductor chips, comprising:
wherein electron-hole pairs are generated in optoelectronic semiconductor chips, and thereby an electric dipole field is generated in the vicinity of the respective optoelectronic semiconductor chip;
wherein a pick-up tool generates an electric field; and
wherein the optoelectronic semiconductor chips are picked up by the pick-up tool during or after the generation of the electron-hole pairs and deposited at predetermined positions.

2. The method according to claim 1, wherein the optoelectronic semiconductor chips are LEDs.

3. The method according to claim 1, wherein the optoelectronic semiconductor chips are irradiated with light having a predetermined wavelength or range of wavelengths to generate the electron-hole pairs.

4. The method according to claim 3, wherein the light for generating the electron-hole pairs is incident on the optoelectronic semiconductor chips through the pick-up tool.

5. The method according to claim 3, wherein the optoelectronic semiconductor chips are arranged on a carrier and the light for generating the electron-hole pairs is incident on the optoelectronic semiconductor chips through the carrier.

6. The method according to claim 1, wherein a plurality of optoelectronic semiconductor chips are provided and the electric dipole fields are generated only in selected optoelectronic semiconductor chips of the plurality of optoelectronic semiconductor chips.

7. The method according to claim 1, wherein the pick-up tool generates an electric field only in predetermined areas.

8. The method according to claim 1, wherein the pick-up tool comprises a plurality of protrusions on a surface facing the optoelectronic semiconductor chips and the optoelectronic semiconductor chips are picked up by the protrusions of the pick-up tool.

9. The method according to claim 1, wherein at least a region of a surface of the pick-up tool facing the optoelectronic semiconductor chips is flat and the optoelectronic semiconductor chips are picked up with the flat region of the pick-up tool.

10. The method according to claim 1, wherein the pick-up tool is in the form of a cylinder that is rolled over the optoelectronic semiconductor chips to pick up the optoelectronic semiconductor chips.

11. The method according to claim 1, wherein for depositing the optoelectronic semiconductor chips the electric field generated by the pick-up tool is changed.

12. The method according to claim 1, wherein the pick-up tool for picking up the optoelectronic semiconductor chips directly contacts and holds the optoelectronic semiconductor chips by means of Van der Waals forces.

13. An apparatus for picking up and depositing optoelectronic semiconductor chips, comprising:
an excitation element for generating electron-hole pairs in optoelectronic semiconductor chips to produce an electric dipole field in the vicinity of the respective optoelectronic semiconductor chip; and
a pick-up tool for picking up and depositing the optoelectronic semiconductor chips, the pick-up tool configured to generate an electric field, then pick up the optoelectronic semiconductor chips with the electron-hole pairs generated by the excitation element and deposit the optoelectronic semiconductor chips at predetermined locations.

14. The apparatus according to claim 13, wherein the excitation element is configured to generate light having a predetermined wavelength or range of wavelengths for generating the electron-hole pairs in the semiconductor optoelectronic chips.

15. The apparatus according to claim 14, wherein the excitation element is arranged such that the light for generating the electron-hole pairs is incident on the optoelectronic semiconductor chips through the pick-up tool or through a carrier on which the optoelectronic semiconductor chips are arranged.

16. The apparatus according to claim 13, wherein the pick-up tool comprises a plurality of protrusions on a surface facing the optoelectronic semiconductor chips and the optoelectronic semiconductor chips are picked up by the protrusions of the pick-up tool.

17. The apparatus according to claim 13, wherein at least a region of a surface of the pick-up tool facing the optoelectronic semiconductor chips is planar and the optoelectronic semiconductor chips are picked up with the planar region of the pick-up tool.

18. The apparatus according to claim 13, wherein the receiving tool is in the form of a cylinder which is rolled over the optoelectronic semiconductor chips to receive the optoelectronic semiconductor chips.
